(19) United States
(12) Patent Application Publication
(10) Pub. No.: US 2024/0057306 A1
(43) Pub. Date: Feb. 15, 2024

(54) SYSTEMS AND METHODS FOR ASSEMBLING AN ELECTRONIC DEVICE

(71) Applicant: Google LLC, Mountain View, CA (US)

(72) Inventors: Luis Chau, Concord, CA (US); Fiona Au, San Francisco, CA (US); Alex Locke, San Francisco, CA (US); Wayman Leung, Los Altos, CA (US)

(73) Assignee: Google LLC, Mountain View, CA (US)

(21) Appl. No.: 18/361,087

(22) Filed: Jul. 28, 2023

Related U.S. Application Data
(60) Provisional application No. 63/396,786, filed on Aug. 10, 2022.

(51) Int. Cl. H05K 13/08; H05K 13/00; H05K 13/04

(52) U.S. Cl. CPC H05K 13/0815; H05K 13/0015; H05K 13/0469; H05K 13/0812; G03B 30/00

(57) ABSTRACT

Features described herein generally relate to systems and methods for assembling an electronic device. Particularly, the electronic device can be assembled by holding a portion of the first component arranged in a first plane in a holding position with a stream of air output from a nozzle of an assembly system and aligning the portion of the first component with an opening in a portion of the second component arranged in a second plane parallel to the first plane while the portion of the first component is held in the holding position.

### CROSS-REFERENCE TO RELATED APPLICATIONS

This application claims the benefit of, and priority to U.S. Provisional Application Ser. No. 63/396,786, filed Aug. 10, 2022, which is hereby incorporated by reference in its entirety for all purposes.

### BACKGROUND

The assembly of electronic devices often involves aligning multiple components within specified assembly tolerances. For example, the assembly of an electronic device can involve aligning a switch of a display to a switch opening in a housing for the electronic device. During the assembly process, these components are often not fixed and are freely movable. For example, as the switch is brought into alignment and eventual contact with the switch opening, movement of the display may cause the switch to move out of position and not align properly with the switch opening. As a result, maintaining alignment of components during electronic device assembly processes is challenging.

### SUMMARY

Embodiments described herein pertain to systems and methods for assembling an electronic device.

According to some embodiments, a method for assembling an electronic device includes arranging a first component of the electronic device in a first position on a first plane; arranging a second component of the electronic device in a second position on a second plane, wherein the second plane is parallel to the first plane and separated from the first plane by a predetermined distance, wherein a position of a portion of the first component on the first plane and a position of a portion of the second component overlap along an axis perpendicular to the first plane and the second plane; holding the portion of the first component in a holding position with a stream of air output from a nozzle of an assembly system; and aligning the portion of the first component with an opening in the portion of the second component while the portion of the first component is held in the holding position.

In some embodiments, the aligning includes: (i) outputting the stream of air from the nozzle; (ii) moving, using one or more actuators of the assembly system, at least one of the first component and the second component in at least one of a direction parallel to at least one of the first plane and second plane and a direction parallel to the axis; (iii) capturing, with at least one camera of the assembly system, a plurality of images, wherein each image of the plurality of images depicts the first component and the second component; (iv) determining whether the portion of the first component is contacting the opening in the portion of the second component; (vi) in response to determining that the portion of the first component is contacting the opening in the portion of the second component, securing the first component to the second component; and (vii) in response to determining that the portion of the first component is not contacting the opening in the portion of the second component, repeatedly performing steps (i)-(iv) until it is determined that the portion of the first component is contacting the opening in the portion of the second component.

In some embodiments, the first component is at least one of a privacy shutter or a display subassembly of the electronic device and the portion of the first component is a protruding portion.

In some embodiments, the second component is a housing of the electronic device and the portion of the second component is a slider arm configured to control an opening state of a privacy shutter.

In some embodiments, the opening in the portion of the second component comprises a slot configured to receive the portion of the first component during the aligning.

In some embodiments, the nozzle is located in a plane parallel to the first plane and the second plane and between the first component and the second component.

In some embodiments, determining whether the portion of the first component is contacting the opening in the portion of the second component includes analyzing the plurality of images using a computer vision algorithm.

In some embodiments, the first plane and second plane extend along an X-axis and a Y-axis of a three-dimensional coordinate system and the axis perpendicular to the first plane and the second plane is parallel to a Z-axis of the three-dimensional coordinate system.

In some embodiments, securing the first component to the second component includes securing the first component to the second component using an adhesive and/or fastener.

Some embodiments include a computer-program product tangibly embodied in one or more non-transitory machine-readable media, including instructions configured to cause an assembly system to perform part or all of the operations and/or methods disclosed herein.

The techniques described above and below may be implemented in a number of ways and in a number of contexts. Several example implementations and contexts are provided with reference to the following figures, as described below in more detail. However, the following implementations and contexts are but a few of many.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 shows a perspective view of an example arrangement of an initial position of a first component and a second component of an electronic device during an assembly process for the electronic device according to some aspects of the present disclosure.

FIG. 2 shows a perspective view of an example arrangement of a final position of the first component and the second component of the electronic device during the assembly process for the electronic device according to some aspects of the present disclosure.

FIG. 3 shows a perspective view of an example arrangement of a nozzle of an assembly system for assembling the electronic device according to some aspects of the present disclosure.

FIG. 4 shows a profile view of an example arrangement of the first component and the second component of the electronic device during the assembly process for the electronic device according to some aspects of the present disclosure.

FIG. 5 shows an example of the assembly system for assembling the electronic device according to some aspects of the present disclosure.

FIG. 6 shows a flowchart of an example process for assembling the electronic device according to some aspects of the present disclosure.

FIG. 7 shows a flowchart of another example process for assembling the electronic device according to some aspects of the present disclosure.

### DETAILED DESCRIPTION

Electronic devices often include multiple components. A typical electronic device, for example, includes a housing with a circuit board, a display component, a sensor component, an audio component, input/output components, and a power supply component that are disposed within the housing. Often each component will include one or more sub-components. For example, a display sub-assembly may include corner brackets for mounting a display thereon. In another example, a power sub-assembly may include a switch for aligning the power sub-assembly to a housing of the electronic device. The assembly of electronic devices often involves aligning multiple components within specified assembly tolerances. For example, the assembly of an electronic device can involve aligning a switch of a display to a switch opening in a housing. During the assembly process, these components are often not fixed and are freely movable. As such, as the switch is brought into alignment and eventual contact with the switch opening, positioning of the display may cause the switch to move out of position and not align properly with the switch opening. As a result, maintaining alignment of components during electronic device assembly processes is challenging.

The following example illustrates a particular challenge pertaining to assembly of an electronic device. An electronic device may include a privacy shutter and a slider arm for opening and closing the privacy shutter. The privacy shutter can be included in a display sub-assembly that is mounted on a housing of the electronic device. The privacy shutter can include a portion which, when engaged with, causes the privacy shutter to move (e.g., move from an open to a closed state and vice versa). On the other hand, the slider arm can be part of a slider mechanism mounted on the housing the electronic device. When the electronic device is assembled, the slider arm can engage with the portion of the privacy shutter to cause the privacy shutter to open and close. When the electronic device is disassembled, the privacy shutter is freely movable and can move based on various forces without engagement by the slider arm. During assembly of the electronic device, the privacy shutter and the slider arm are aligned by moving the display sub-assembly and/or the housing in an X-Y plane and are brought into contact with each other by moving the display sub-assembly and/or the housing in a Z-direction towards each other. As these components are moved, gravitational forces, vibration due to the manufacturing environment, and other forces applied to the display sub-assembly can cause the privacy shutter to move. Physically contacting a component to hold it a certain position increases the potential for damaging the component. Moreover, due to the space constraints between the display sub-assembly and the slider mechanism during the assembly process, the ability to physically manipulate the privacy shutter to hold it in a fixed position is limited by space constraints. As a result, keeping the slider arm aligned with the portion of the privacy shutter during the assembly process is challenging, can risk damaging the components, and can require additional process time on expensive equipment.

The techniques described herein overcome the foregoing challenges and others by providing systems and methods for assembling an electronic device that uses pressurized air to hold a privacy shutter in a fixed position during the assembly process. The features described herein include a method for assembling an electronic device that includes arranging a first component of the electronic device in a first position on a first plane and arranging a second of the electronic device in a second position on a second plane that is parallel to the first plane and separated from the first plane by a predetermined distance. A position of a portion of the first component on the first plane and a position of a portion of the second component on the second plane overlap along an axis that is perpendicular to the first plane and the second plane. The portion of the first component is held in a holding position with a stream of air output from a nozzle of an assembly system. The nozzle is located in a plane parallel to the first plane and second plane and between the first component and the second component. The portion of the first component is aligned with an opening in the portion of the second component while the portion of the first component is held in the holding position. The first plane and the second plane can extend along an X-axis and Y-axis of a three-dimensional coordinate system and the axis perpendicular to the first plane and the second plane is parallel to a Z-axis of the three-dimensional coordinate system.

The aligning process includes: outputting the stream of air from the nozzle; moving at least one of the first component and the second component in at least one of a direction parallel to at least one of the first plane and second plane and a direction parallel to the axis using one or more actuators of the assembly system; capturing a plurality of images with at least one camera of the assembly system such that each image of the plurality of images depicts the first component and the second component; and determining whether the portion of the first component is contacting the opening in the portion of the second component. The determination can be made by analyzing the captured images using a computer vision algorithm. In response to determining that the portion of the first component is contacting the opening in the portion of the second component, the first component is secured to the second component using an adhesive and/or fastener. In response to determining that the portion of the first component is not contacting the opening in the portion of the second component, the aligning process is repeated until it is determined that the portion of the first component is contacting the opening in the portion of the second component.

The electronic device described herein can be any kind of electronic device that includes multiple components. Examples of electronic devices include but are not limited to tablets and computing devices (e.g., Google® Pixel® Tablet), smart display/assistant devices (e.g., Google® Nest® Hub), smart phones and communication devices (e.g., Google® Pixel® Phone), and the like. As such, in some implementations, the first component of the electronic device can be at least one of a privacy shutter or a display subassembly of the electronic device and the portion of the first component can be a protruding portion of the privacy shutter. Additionally, in some implementations, the second component can be a housing of the electronic device and the portion of the second component is a slider arm that is configured to control an opening state of the privacy shutter. The opening in the portion of the second component can include a slot that is configured to receive the portion of the first component during the aligning process.

The non-contact positioning described herein is not limited to positioning the components described above but can be applied to align other components in an assembly process, particularly components that are delicate and/or hard to reach using physical contact. Using the techniques described herein, an electronic device including multiple components can be assembled with proper alignment between components without increasing the potential for damage to the components, in reduced process time, and with less resources. Additionally, using the techniques described herein, components of an electronic device can be aligned in even in limited space constraints. Other features and advantages will become apparent in the descriptions below.

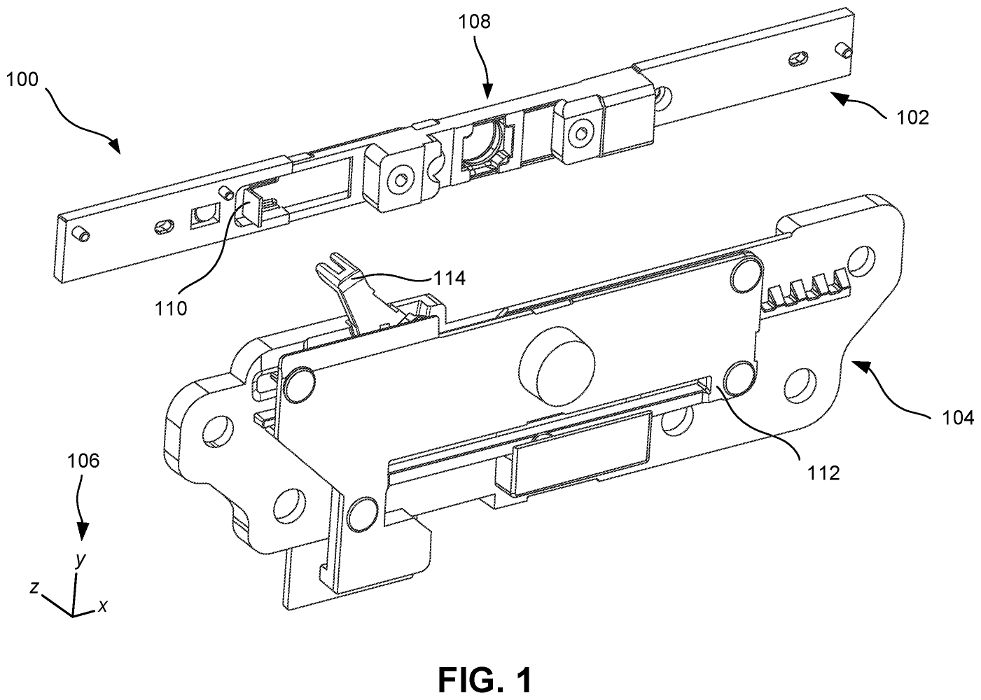

FIG. 1 shows a perspective view 100 of an example arrangement of components of an electronic device during an assembly process of the electronic device. As shown in FIG. 1, an electronic device (not shown) can include a first component 102 (e.g., a display sub-assembly) and a second component 104 (e.g., a housing). At the start of the assembly process, the first component 102 can be arranged in a first initial position on a first plane and the second component 104 can be arranged in a second initial position on a second plane. In some implementations, the first and second planes can be planes that extend along an X-axis and Y-axis included in a coordinate system such as three-dimensional (3D) coordinate system 106. For example, the second plane can be parallel to the first plane and separated from the first plane by a predetermined distance along a Z-axis of the coordinate system 106. In some implementations, the first component 102 is a display sub-assembly that includes a privacy shutter 108 and a protruding portion 110 and the second component 104 is a housing of the electronic device that includes a slider arm 114 and slider mechanism 112.

During the assembly process, the first and second components 102, 104 can be brought into alignment and secured with each other. To effectuate the alignment and securing, one or more actuators of an assembly system (not shown) can move the first component 102 from the first initial position on the first plane to one or more second positions on the first plane and move the first component 102 in a direction extending along the Z-axis of the coordinate system 106 from the first plane to one or more intermediate planes between the first plane and the second plane. Similarly, during the assembly process, the one or more actuators can also move the second component 104 from the second initial position on the second plane to one or more second positions on the second plane and move the second component 104 in a direction extending along the Z-axis of the coordinate system 106 from the second plane to the one or more intermediate planes between the second plane and the first plane.

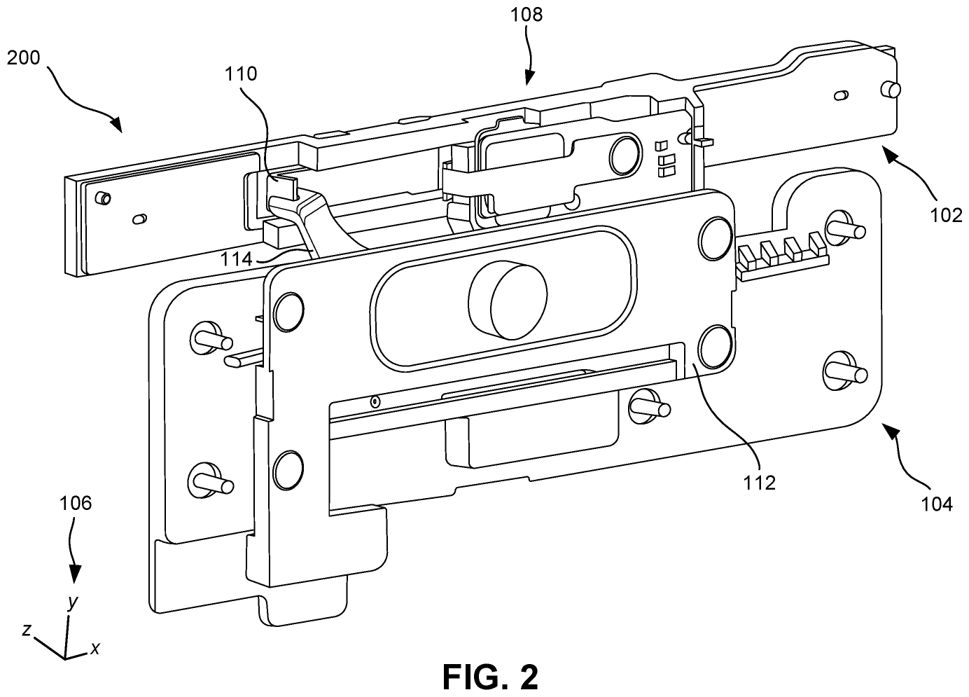

The slider arm 114 of the second component 104 can include an opening for receiving the protruding portion 110 of the privacy shutter 108. The opening can include a slot that is configured to receive the protruding portion 110 of the privacy shutter 108. While the first component 102 is being moved, the privacy shutter 108 can move freely along a direction extending along the X-axis of the coordinate system 106. In some embodiments, the privacy shutter 108 can move freely from a first end position to a second end position and vice versa. For example, the privacy shutter 108 can move in a slot from one end of the slot to another end of the slot. In this way, during the assembly process, as shown in FIG. 2, as the first and second components 102, 104 are moved from their first and second initial positions and in the direction extending along the Z-axis, as described above, the protruding portion 110 of the privacy shutter 108 can be aligned with and brought into contact with the opening of the slider arm 114. In some embodiments, after the protruding portion 110 of the privacy shutter 108 is aligned with and brought into contact with the slot of the opening of the slider arm 114, the first component 102 is secured to the second component 104. In some embodiments, the first component 102 is secured to the second component 104 using an adhesive, one or more fasteners, or a combination thereof.

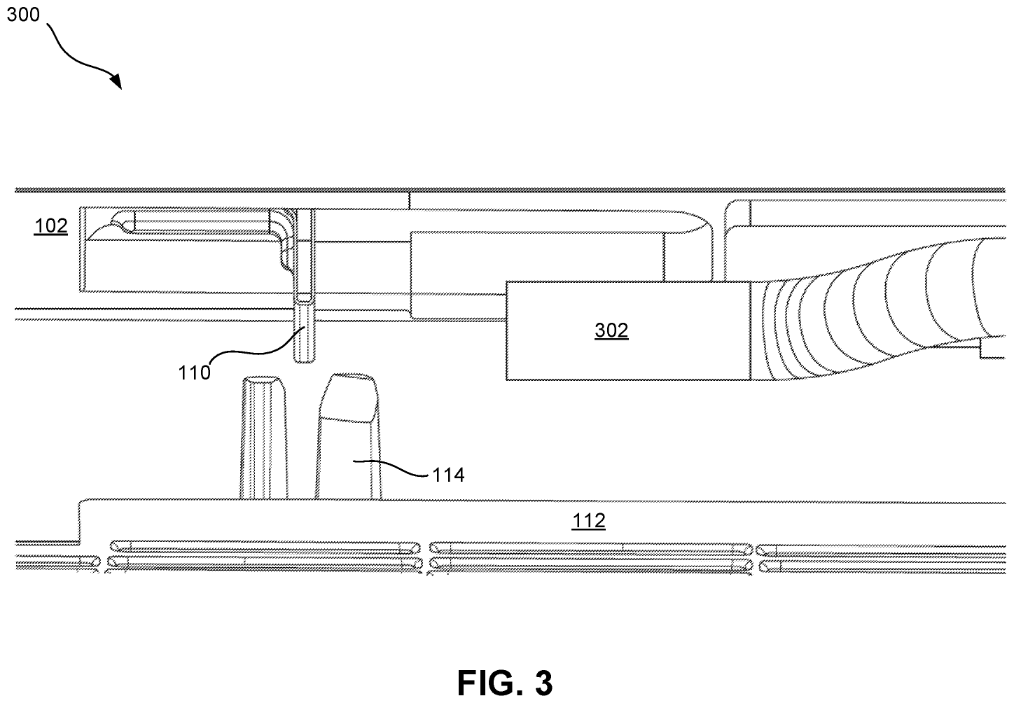

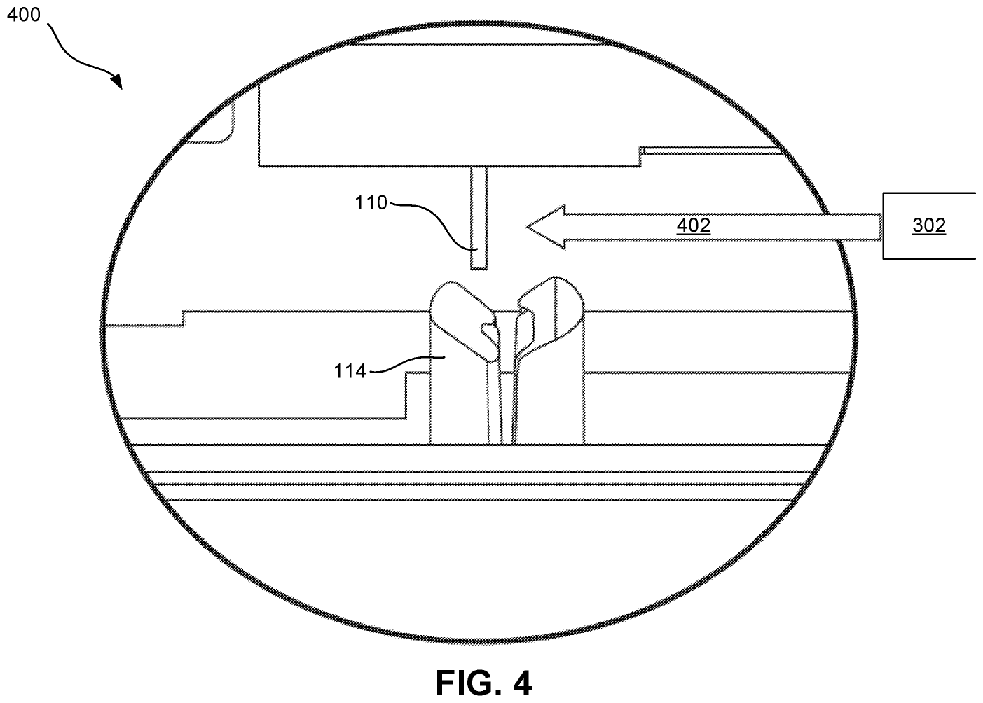

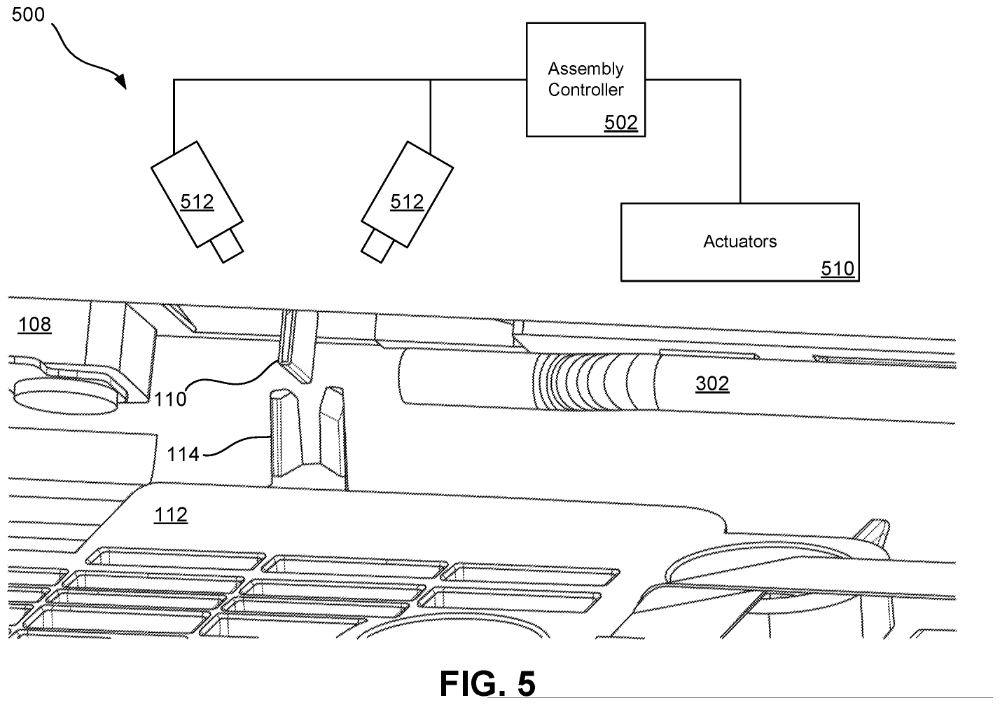

As described above, while the first component 102 is being moved, the privacy shutter 108 can move freely along a direction extending along the X-axis of the coordinate system 106. As such, during assembly of the electronic device, the protruding portion 110 of the privacy shutter 108 may not align properly with the opening of the slider arm 114. To ensure that that the protruding portion 110 of the privacy shutter 108 maintains alignment with the slot of the opening of the slider arm 114 during the assembly process, a stream of air can be applied to the protruding portion 110. The stream of air can be pressurized and/or compressed and configured to apply a force to the protruding portion 110 to hold the protruding portion 110 in a fixed position and/or otherwise prevent the protruding portion 110 from moving due to unintended movements of the first component 102, the privacy shutter 108, and the protruding portion 110 while the first component 102 is being moved. In some embodiments, the fixed position can correspond to the first end position or the second end position described above. In other embodiments, the fixed position can correspond to a position between the first end position and the second end position. The stream of air can be output from a nozzle. The nozzle can be a component of an assembly system (FIG. 5). As shown in FIG. 3, the nozzle 302 can be located in a plane parallel to the first plane and second plane and between the first component 102 and the second component 104 and oriented such that the stream of air output from the nozzle 302 flows in a direction towards the protruding portion 110. The stream of air can be configured to be output from the nozzle 302 towards the protruding portion 110 at a set velocity or pressure. In some embodiments, the stream of air can be configured to be output from the nozzle 302 towards the protruding portion 110 at variable velocities or pressures. For example, as shown in FIG. 4, which shows a profile view 400 of an example arrangement of the first component 102 and the second component 104 during the assembly process, a compressed stream of air 402 is output from the nozzle 302 and flows in a direction towards the protruding portion 110 of the privacy shutter 108 such that the protruding portion 110 of the privacy shutter 108 can be held in a position while being aligned with the slot of the opening of the slider arm 114.

In some embodiments, cameras (FIG. 5) can be provided to capture images and/or video frames of the first component 102, the privacy shutter 108, the protruding portion 110, the second component 104, the slider mechanism 112, and the slider arm 114. The cameras can be part of the assembly system and located in an environment surrounding the first and second components 102 and 104 and oriented in such a way that a field of view of each camera can capture images and/or video frames of the first component 102, the privacy shutter 108, the protruding portion 110, the second component 104, the slider mechanism 112, and the slider arm 114. The captured images and/or video frames can be input into a computer vision algorithm to determine whether the protruding portion 110 of the privacy shutter 108 and the slot of the opening of the slider arm 114 are in proper alignment. In some embodiments, the protruding portion 110 of the privacy shutter 108 and the slot of the opening in the slider arm 114 are in proper alignment when the protruding portion 110 of the privacy shutter 108 is between and in contact with first and second walls of the slot of the opening of the slider arm 114. In some embodiments, the cameras can be configured to capture images and/or video frames at a predetermined interval or frame rate (e.g., 30 frames per second). The computer vision algorithm can be configured to receive the images and/or video frames and determine a 3D relative position between the protruding portion 110 of the privacy shutter 108 and the first and second walls of the slot of the opening of the slider arm 114. The computer vision algorithm can use the 3D relative position to determine how much the first component 102 and/or second component 104 should be moved and in what direction the first component 102 and/or second component 104 should be moved in in order to align the protruding portion 110 with the first and second walls of the slot. Additionally, the computer vision algorithm can determine the velocity/velocities or pressure/pressures in which the stream of air should be output from the nozzle 302. In this way, even though the privacy shutter 108 can move freely, the protruding portion 110 of the privacy shutter 108 can be immobilized with the stream of air and be properly aligned with the opening of the slider arm 114 without physically manipulating and/or contacting the privacy shutter 108, the protruding portion 114, the slider mechanism 112, and the slider arm 114.

In some embodiments, to properly align the protruding portion 110 of the privacy shutter 108 with the opening in the slider arm 114, the following process steps can be taken: a stream of air is output from the nozzle; at least one of the first component and the second component is moved in at least one of a direction parallel to at least one of the first plane and second plane and a direction parallel to the axis using one or more actuators of the assembly system; a plurality of images are captured with at least one camera of an assembly system such that each image of the plurality of images depicts the first component and the second component; and a determination is made whether the portion of the first component is contacting the opening in the portion of the second component. The determination can be made by analyzing the images using a computer vision algorithm. In response to determining that the portion of the first component is contacting the opening in the portion of the second component, the first component is secured to the second component using an adhesive and/or fastener. In response to determining that the portion of the first component is not contacting the opening in the portion of the second component, the aligning process is repeated until it is determined that the portion of the first component is contacting the opening in the portion of the second component.

FIG. 5 shows an example of the assembly system 500 for assembling the electronic device. As shown in FIG. 5, the assembly system 500 can include an assembly controller 502, cameras 512, actuators 510, and nozzle 302. The assembly system 500 is configured to assemble the electronic device. Particularly, while assembling the electronic device, the assembly system 500 is configured to facilitate the proper alignment of the protruding portion 110 of the privacy shutter 108 with the opening in the slider arm 114 using part or all of the techniques described herein. The assembly controller 502 can include a processing system (not shown) that can include one or more general-purpose processors or special-purpose processors that are specifically designed to perform the functions of the assembly controller 502. Such special-purpose processors can be application-specific integrated circuits (ASICs), field-programmable gate arrays (FPGAs), and programmable logic devices (PLDs) which are general-purpose components that are physically and electrically configured to perform the functions detailed herein. Such general-purpose processors can execute special-purpose software that is stored using one or more non-transitory processor-readable mediums, such as random-access memory (RAM), flash memory, a hard disk drive (HDD), or a solid-state drive (SSD). Examples of general-purpose processors include microprocessors, microcontrollers, central processing units, graphical processing units, digital signal processors, ASICs, FPGAs, PLDs, or any combination thereof. The general-purpose processors can include a plurality of cores, a plurality of arrays, one or more coprocessors, and/or one or more layers of local cache memory.

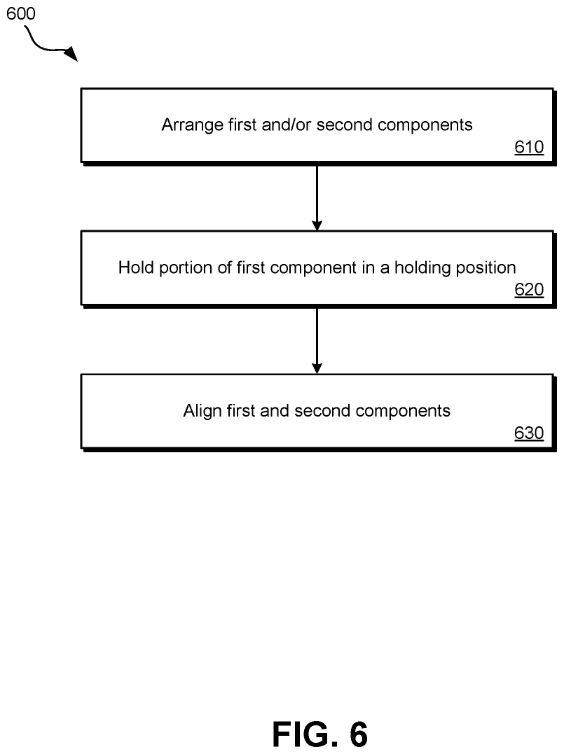

FIG. 6 shows a flowchart of an example process 600 for assembling an electronic device. In some embodiments, the process 600 can be implemented by assembly system 500. The process 600 can be implemented in software, hardware, or any combination thereof.

At block 610, a first component and/or second component of the electronic device is arranged. The first component can be arranged in a first position on a first plane that extends along an X-axis and Y-axis of a 3D coordinate system. The second component of the electronic device can be arranged in a second position on a second plane that also extends along the X-axis and Y-axis of the 3D coordinate system. The second plane can be parallel to the first plane and separated from the first plane by a predetermined distance. A position of a portion of the first component on the first plane and a position of a portion of the second component can overlap along an axis perpendicular to the first plane and the second plane. The axis perpendicular to the first plane and the second plane can be parallel to a Z-axis of the 3D coordinate system. In some implementations, the first component is at least one of a privacy shutter or a display subassembly of the electronic device and the portion of the first component is a protruding portion of the privacy shutter or display subassembly. In some implementations, the second component is a housing of the electronic device and the portion of the second component is a slider arm configured to control an opening state of a privacy shutter. In some implementations, the portion of the second component can include an opening that includes a slot that is configured to receive the portion of the first component.

At block 620, the portion of the first component is held in a holding position with a stream of air. The stream of air can be output from a nozzle of an assembly system at a set velocity and/or a variable velocity. In some implementations, the nozzle is located in a plane parallel to the first plane and second plane and between the first component and the second component.

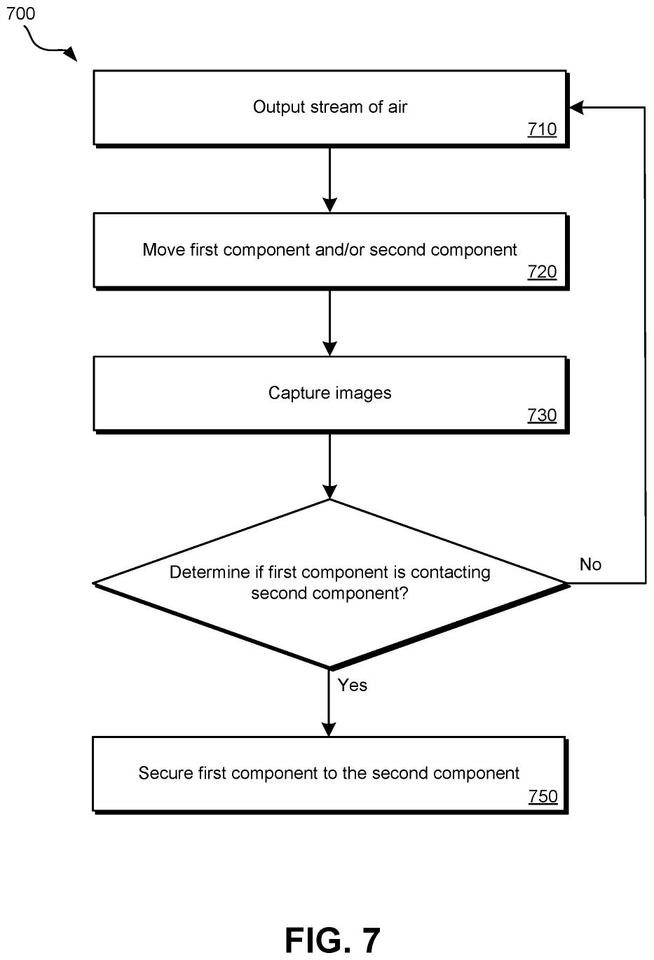

At block 630, the portion of the first component is aligned with the opening in the portion of the second component. In some embodiments, the portion of the first component is aligned with the opening in the portion of the second component while the portion of the first component is held in the holding position. The alignment process is described below with respect to FIG. 7.

FIG. 7 shows a flowchart of another example process 700 for assembling the electronic device. In some embodiments, the process 700 can be implemented by assembly system 500. The process 700 can be implemented in software, hardware, or any combination thereof.

At block 710, the stream of air is output from the nozzle. In some implementations, the stream of air is output from the nozzle at a set velocity and/or a variable velocity.

At block 720, at least one of the first component and the second component is moved in at least one of a direction parallel to at least one of the first plane and second plane and a direction parallel to the axis. In some implementations, the first component and the second component can be moved using one or more actuators of the assembly system.

At block 730, a plurality of images is captured. Each image of the plurality of images depicts the first component and the second component.

At block 740, a determination is made whether the portion of the first component is contacting the opening in the portion of the second component. Determining whether the portion of the first component is contacting the opening in the portion of the second component includes analyzing the plurality of images using a computer vision algorithm. In response to determining that the portion of the first component is contacting the opening in the portion of the second component, at block 750, the first component is secured to the second component. In some implementations, the first component can be secured to the second component using an adhesive and/or fastener. On the other hand, if response to determining that the portion of the first component is not contacting the opening in the portion of the second component, repeatedly performing blocks 710-740 until it is determined that the portion of the first component is contacting the opening in the portion of the second component.

The systems and methods of the present disclosure may be implemented using hardware, software, firmware, or a combination thereof and may be implemented in one or more computer systems or other processing systems. Some embodiments of the present disclosure include a system including a processing system that includes one or more processors. In some embodiments, the system includes a non-transitory computer readable storage medium containing instructions which, when executed on the one or more processors, cause the system and/or the one or more processors to perform part or all of one or more methods and/or part or all of one or more processes disclosed herein. Some embodiments of the present disclosure include a computer-program product tangibly embodied in a non-transitory machine-readable storage medium, including instructions configured to cause the system and/or the one or more processors to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention as claimed has been specifically disclosed by embodiments and optional features, modification, and variation of the concepts herein disclosed may be resorted to by those skilled in the art, and that such modifications and variations are considered to be within the scope of this invention as defined by the appended claims.

Specific details are given in the following description to provide a thorough understanding of the embodiments. However, it will be understood that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

The above description of certain examples, including illustrated examples, has been presented only for the purpose of illustration and description and is not intended to be exhaustive or to limit the disclosure to the precise forms disclosed. Modifications, adaptations, and uses thereof will be apparent to those skilled in the art without departing from the scope of the disclosure. For instance, any examples described herein can be combined with any other examples.

What is claimed is:

1. A method for assembling an electronic device, the method comprising:
arranging a first component of the electronic device in a first position on a first plane;
arranging a second component of the electronic device in a second position on a second plane, wherein the second plane is parallel to the first plane and separated from the first plane by a predetermined distance, wherein a position of a portion of the first component on the first plane and a position of a portion of the second component overlap along an axis perpendicular to the first plane and the second plane;
holding the portion of the first component in a holding position with a stream of air output from a nozzle of an assembly system; and
aligning the portion of the first component with an opening in the portion of the second component while the portion of the first component is held in the holding position, the aligning comprising:
(i) outputting the stream of air from the nozzle;
(ii) moving, using one or more actuators of the assembly system, at least one of the first component and the second component in at least one of a direction parallel to at least one of the first plane and second plane and a direction parallel to the axis;
(iii) capturing, with at least one camera of the assembly system, a plurality of images, wherein each image of the plurality of images depicts the first component and the second component;
(iv) determining whether the portion of the first component is contacting the opening in the portion of the second component;
(vi) in response to determining that the portion of the first component is contacting the opening in the portion of the second component, securing the first component to the second component; and
(vii) in response to determining that the portion of the first component is not contacting the opening in the portion of the second component, repeatedly performing steps (i)-(iv) until it is determined that the portion of the first component is contacting the opening in the portion of the second component.

2. The method of claim 1, wherein the first component is at least one of a privacy shutter or a display subassembly of the electronic device and the portion of the first component is a protruding portion.

3. The method of claim 1, wherein the second component is a housing of the electronic device and the portion of the second component is a slider arm configured to control an opening state of a privacy shutter.

4. The method of claim 3, wherein the opening in the portion of the second component comprises a slot configured to receive the portion of the first component during the aligning.

5. The method of claim 1, wherein the nozzle is located in a plane parallel to the first plane and the second plane and between the first component and the second component.

6. The method of claim 1, wherein determining whether the portion of the first component is contacting the opening in the portion of the second component comprises analyzing the plurality of images using a computer vision algorithm.

7. The method of claim 1, wherein the first plane and second plane extend along an X-axis and a Y-axis of a three-dimensional coordinate system.

8. The method of claim 7, wherein the axis perpendicular to the first plane and the second plane is parallel to a Z-axis of the three-dimensional coordinate system.

9. The method of claim 1, wherein securing the first component to the second component comprises securing the first component to the second component using an adhesive and/or fastener.

10. A computer-program product tangibly embodied in one or more non-transitory machine-readable media, including instructions configured to cause an assembly system to perform operations comprising:
arranging a first component of an electronic device in a first position on a first plane;
arranging a second component of the electronic device in a second position on a second plane, wherein the second plane is parallel to the first plane and separated from the first plane by a predetermined distance, wherein a position of a portion of the first component on the first plane and a position of a portion of the second component overlap along an axis perpendicular to the first plane and the second plane;
holding the portion of the first component in a holding position with a stream of air output from a nozzle of an assembly system; and
aligning the portion of the first component with an opening in the portion of the second component while the portion of the first component is held in the holding position, the aligning comprising:
(i) outputting the stream of air from the nozzle;
(ii) moving, using one or more actuators of the assembly system, at least one of the first component and the second component in at least one of a direction parallel to at least one of the first plane and second plane and a direction parallel to the axis;
(iii) capturing, with at least one camera of the assembly system, a plurality of images, wherein each image of the plurality of images depicts the first component and the second component;
(iv) determining whether the portion of the first component is contacting the opening in the portion of the second component;
(vi) in response to determining that the portion of the first component is contacting the opening in the portion of the second component, securing the first component to the second component; and
(vii) in response to determining that the portion of the first component is not contacting the opening in the portion of the second component, repeatedly performing steps (i)-(iv) until it is determined that the portion of the first component is contacting the opening in the portion of the second component.

11. The computer-program product of claim 10, wherein the first component is at least one of a privacy shutter or a display subassembly of the electronic device and the portion of the first component is a protruding portion.

12. The computer-program product of claim 10, wherein the second component is a housing of the electronic device and the portion of the second component is a slider arm configured to control an opening state of a privacy shutter.

13. The computer-program product of claim 12, wherein the opening in the portion of the second component comprises a slot configured to receive the portion of the first component during the aligning.

14. The computer-program product of claim 10, wherein the nozzle is located in a plane parallel to the first plane and the second plane and between the first component and the second component.

15. The computer-program product of claim 10, wherein determining whether the portion of the first component is contacting the opening in the portion of the second component comprises analyzing the plurality of images using a computer vision algorithm.

16. The computer-program product of claim 10, wherein the first plane and second plane extend along an X-axis and a Y-axis of a three-dimensional coordinate system.

17. The computer-program product of claim 16, wherein the axis perpendicular to the first plane and the second plane is parallel to a Z-axis of the three-dimensional coordinate system.

18. The computer-program product of claim 10, wherein securing the first component to the second component comprises securing the first component to the second component using an adhesive and/or fastener.

19. A method for assembling an electronic device, the method comprising:
arranging a first component of the electronic device in a first position on a first plane;
arranging a second component of the electronic device in a second position on a second plane, wherein the second plane is parallel to the first plane and separated from the first plane by a predetermined distance, wherein a position of a portion of the first component on the first plane and a position of a portion of the second component overlap along an axis perpendicular to the first plane and the second plane;
holding the portion of the first component in a holding position with a stream of air output from a nozzle of an assembly system; and
aligning the portion of the first component with an opening in the portion of the second component while the portion of the first component is held in the holding position.

20. The method of claim 19, wherein the aligning comprises:
(i) outputting the stream of air from the nozzle;
(ii) moving, using one or more actuators of the assembly system, at least one of the first component and the second component in at least one of a direction parallel to at least one of the first plane and second plane and a direction parallel to the axis;
(iii) capturing, with at least one camera of the assembly system, a plurality of images, wherein each image of the plurality of images depicts the first component and the second component;
(iv) determining whether the portion of the first component is contacting the opening in the portion of the second component;
(vi) in response to determining that the portion of the first component is contacting the opening in the portion of the second component, securing the first component to the second component; and
(vii) in response to determining that the portion of the first component is not contacting the opening in the portion of the second component, repeatedly performing steps (i)-(iv) until it is determined that the portion of the first component is contacting the opening in the portion of the second component.
